(19) United States
(12) Patent Application Publication
(10) Pub. No.: US 2004/0232978 A1
(43) Pub. Date: Nov. 25, 2004

(54) Filterless class D amplifiers using spread spectrum PWM modulation

(76) Inventors: Craig Alexander Easson, Sunnyvale, CA (US); Christopher Francis Edwards, Sunnyvale, CA (US); Madhavprasad V. Kolluri, Sunnyvale, CA (US); Anthony Stephen Doy, Sunnyvale, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/444,547

(22) Filed: May 23, 2003

(51) Int. Cl. H03F 3/38; H03F 3/217

(52) U.S. Cl. 330/10; 330/251

(57) ABSTRACT

Filterless class D amplifier using spread spectrum pulse width modulation with feedback to suppress low frequency noise in the amplifier output. The amplifiers may use any of a wide variety of pulse width modulators with a dynamically variable frequency ramp or triangular waveform to whiten the output noise of the amplifier. Typically the ramp or triangular waveform input to the modulators is randomly or pseudo randomly varied over some percentage about a nominal frequency. Various feedback techniques for suppressing the low frequency noise are disclosed. Using this invention, Electromagnetic Interference (EMI) emissions from the circuit can be kept substantially below regulatory requirements without the need for expensive external filtering and/or shielding external to the integrated circuit.

### BACKGROUND OF THE INVENTION

1. Field of the Invention

The present invention relates to the field of class D amplifiers.

2. Prior Art

Class D (audio) amplifiers and switched mode DC-DC power supplies can output fast, high voltage and high current transients that can result in the emission of significant high frequency electromagnetic interference (EMI). This EMI can couple into unrelated systems in the vicinity of the emitter, causing undesirable performance degradation. In the case of a class D audio amplifier, usually an external passive filter with at least 2 high current inductors is used to mitigate these effects, at the expense of doubling the cost and quadrupling the PCB space required to implement the class D amplifier compared with an equivalent linear class A or class AB audio amplifier design.

Often the amplifier or power supply utilizes pulse-width modulation (PWM) to convert a linear signal to a square wave with a duty cycle proportional to the linear signal. In fact, it is the high bandwidth of the square wave that ultimately causes the EMI problems. By way of example, in the prior art of FIG. 1, a class D amplifier uses a pulse width modulator to generate a square waveform whose duty cycle is varied depending on the input signal. The square wave drives an H bridge that generates a differential square waveform to output to the speaker load. It is well understood that such a system enables very high efficiencies compared to a linear class A or class AB amplifier for most audio applications. Conventionally, a passive low pass filter is placed between the H bridge and speaker to filter the square waveform and recover the audio signal. The action of the low pass filter in reducing the high frequency content of the waveforms reduces the EMI of the complete circuit, particularly in such applications where the speaker is placed some distance from the amplifier H bridge circuit, as is often the case.

Referring to the prior art of FIG. 2, a class D amplifier is often placed in a negative feedback loop where the filtered audio output is compared with the input signal and the resulting waveform passed through a low pass filter before being passed to the modulator. Such a system can enable improvements in the distortion performance of the class D amplifier by correcting the non-ideal effects of the H bridge, such as finite rise/fall times and switch dead time.

### BRIEF DESCRIPTION OF THE DRAWINGS

FIGS. 1 and 2 are diagrams of exemplary prior art class D amplifiers.

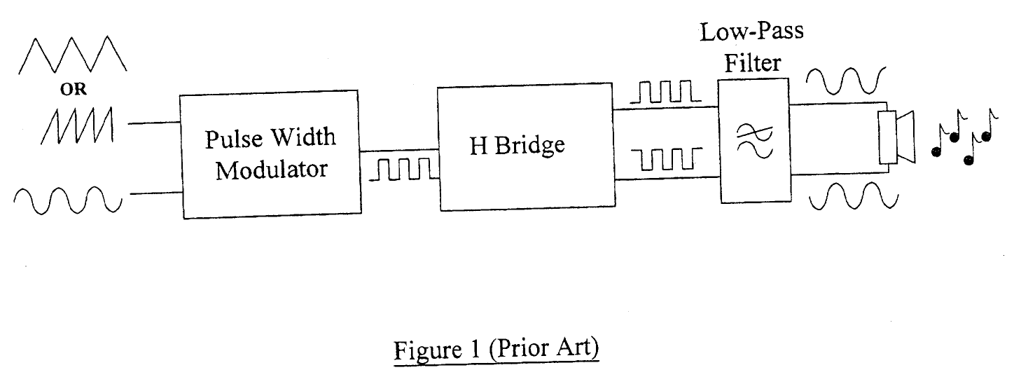

FIG. 3 is a diagram of one embodiment of the present invention.

FIG. 4 is a circuit diagram for an exemplary H bridge that may be used in one embodiment of the present invention.

FIGS. 5a though 5c illustrate exemplary waveforms for the random or pseudo random pulse width modulators.

FIG. 6 illustrates the square waveform output of the pulse width modulator using a pseudo random modulator frequency.

FIG. 7 is a diagram illustrating another embodiment of the present invention.

FIG. 8 is a diagram illustrating still another embodiment of the present invention.

FIG. 9 is a circuit diagram for an alternate/form of H bridge that may be used with certain embodiments of the present invention.

FIG. 10 illustrates a common mode idle modulator that may be used with the present invention.

FIGS. 11, 12 and 13 present modulator output waveforms for common mode idle, ternary and minimum pulse systems, respectively.

FIG. 14 illustrates a ternary modulator that may be used with the present invention.

FIG. 15 illustrates a minimum pulse modulator that may be used with the present invention.

FIG. 16 presents a block diagram for an exemplary logic circuit L1 of the modulator of FIG. 15.

FIG. 17 presents a block diagram for an alternate exemplary logic circuit L1 of the modulator of FIG. 15.

FIG. 18 is a diagram illustrating one method of generating a sawtooth waveform with a variable frequency.

FIG. 19 is a diagram illustrating that the functions of differencing the output signals and subsequent subtraction from the input signal can be implicit to the function of the low pass filter, rather than separate functional blocks.

### DETAILED DESCRIPTION OF THE PREFERRED EMBODIMENTS

One way of reducing the EMI problem is to use spread spectrum techniques to flatten (whiten) the high frequency content of the square waveform by shifting its edges dynamically in time. This is disclosed in co-pending patent application Ser. No. ______, filed concurrently herewith. As disclosed therein, the sawtooth ramp or the ramps defining a triangular wave for the pulse width modulator or modulators may be varied in slope, cycle to cycle or ramp to ramp, preferably in a random or pseudo random manner. This spreads the noise over a broad frequency range, substantially lowering the noise content at frequencies where it would otherwise be too high to meet EMI requirements.

The use of such a spread spectrum technique is advantageous, independent of the modulation technique used. By way of example, some of the Figures herein suggest its use with a classical class D amplifier driving a load through an H bridge. In that technique, an input signal, which may be a single ended signal, is passed through a pulse width modulator to obtain a square wave having a duty cycle proportional to the then present input signal. The H bridge is configured to turn on one pair of switches to couple the power supply to the load with one polarity when the modulator output is low, and to couple the power supply to the load with the opposite polarity when the modulator output is high.

However, as shall be more fully described herein, the present invention is also applicable to other modulation techniques, such as a ternary modulation technique (see U.S. Pat. Nos. 5,077,539 and 6,211,728) wherein two square waves are generated from the input signal. The polarity of the differential between the square waves controls the switches like the classical class D amplifier just described, with the common mode of the two square waves coupling both ends of the load to the positive power supply line or the negative power supply line, depending on the state of the common mode voltage (high or low). Either way, the load is shorted during this time, which for an inductive load such as an audio speaker, reduces the EMI.

Also applicable to the present invention are the modulation techniques described in the co-pending application previously mentioned. That application discloses novel ternary modulation techniques that avoid nonlinearities in the output of a class D amplifier by avoiding partial switching of switches in the H bridge. In particular, when a pulse from one of the modulators is too short to adequately switch the power switches in the H bridge, a pulse of the same polarity is added in common mode, typically by extending the short pulse and adding a common mode pulse to the opposite signal equivalent in length to the extension. This assures proper switching of the power devices in the H bridge, but since the differential signal is not changed, does not effect the power delivered to the load. For substantial input signals, no pulse is added, thereby not encroaching on the potential output range of the amplifier.

In any event, using spread spectrum techniques can introduce additional noise in the amplifier output at low frequencies and degrade the signal-to-noise ratio in the audio band. The present invention applies spread spectrum techniques to a pulse width modulated (PWM) signal waveform in such a way that the high frequency spectrum of the PWM signal is substantially flat, while at the same time the audio content of the waveform at low frequency maintains a high signal-to-noise ratio. The invention helps enable the use of high performance class D amplifiers without the need for costly output filters.

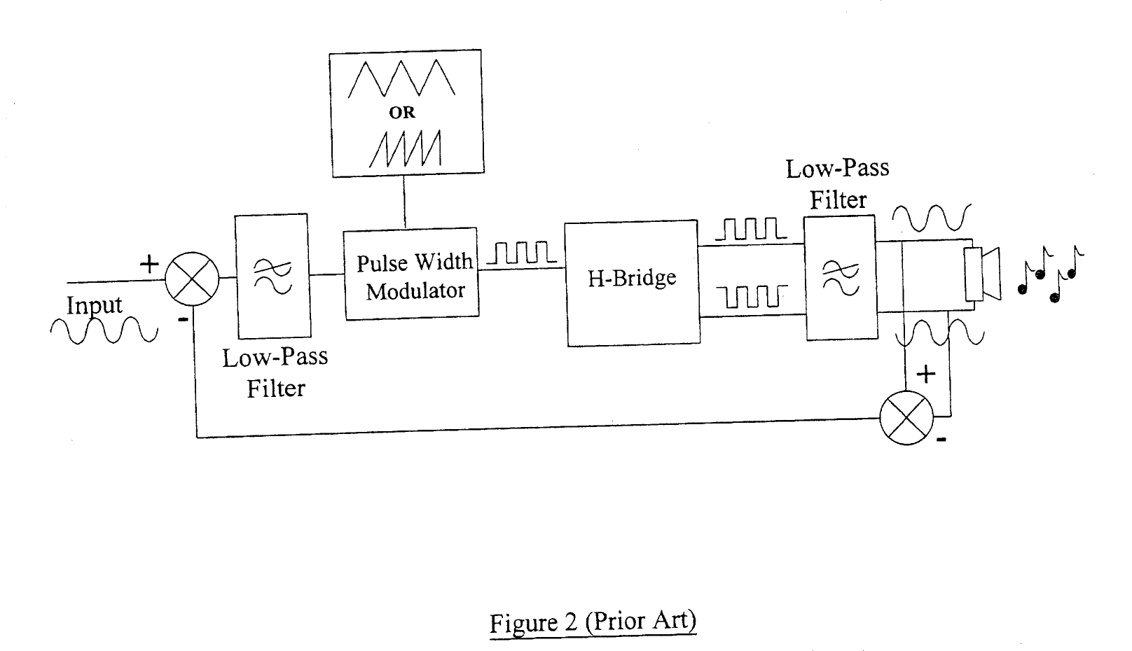

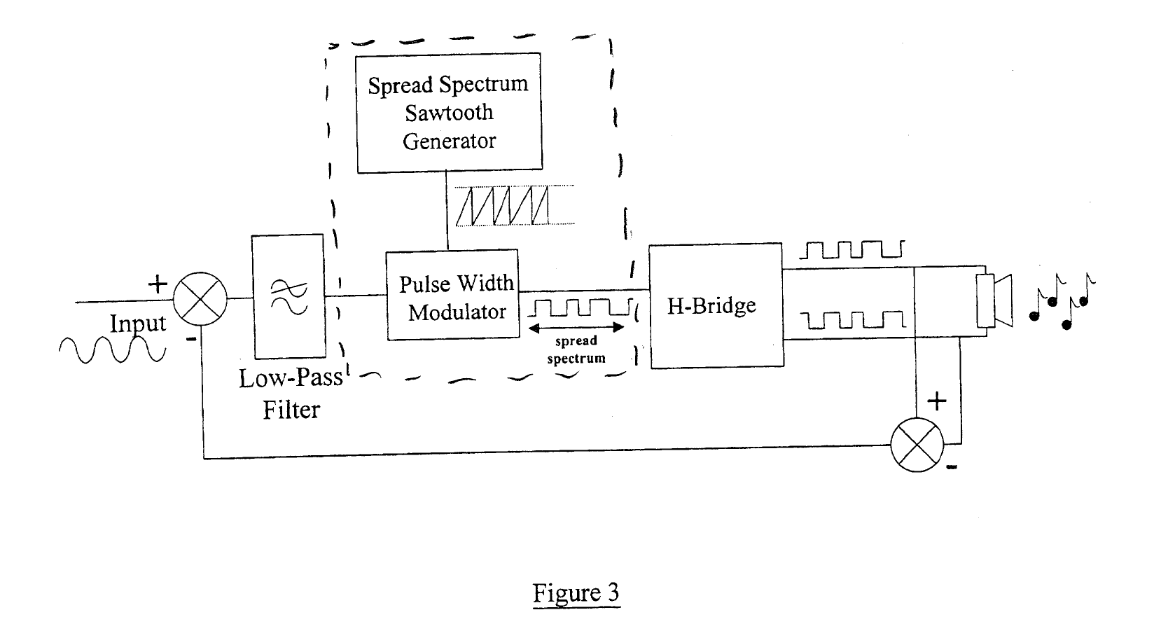

Now referring to FIG. 3, one embodiment of the present invention may be seen. In this embodiment, the pulse width modulator may be of conventional design, with the output thereof being a square wave of a duty cycle responsive to the input. An exemplary H bridge for this embodiment may be seen in FIG. 4. The input of the H bridge is the output of the pulse width modulator shown within the dashed block of FIG. 3, with inverter I1 inverting the square wave to also provide the inverse wave form. With the square wave at the low state, p-channel transistor P1 is on and n-channel transistor N1 is off. Also because of inverter I1, n-channel transistor N2 is on and p-channel transistor P2 is off. This connects the left side of the load to the positive power supply and the right side of the load to the circuit ground. When the square wave input goes high, transistors P1 and N2 turn off and transistors P2 and N1 turn on, again connecting the load (such as the speaker of FIG. 3) across the power supply, but now with the reverse polarity. Thus, the load is always coupled across the power supply with one polarity or the other, the duty cycle of the connections replicating the duty cycle of the modulator output.

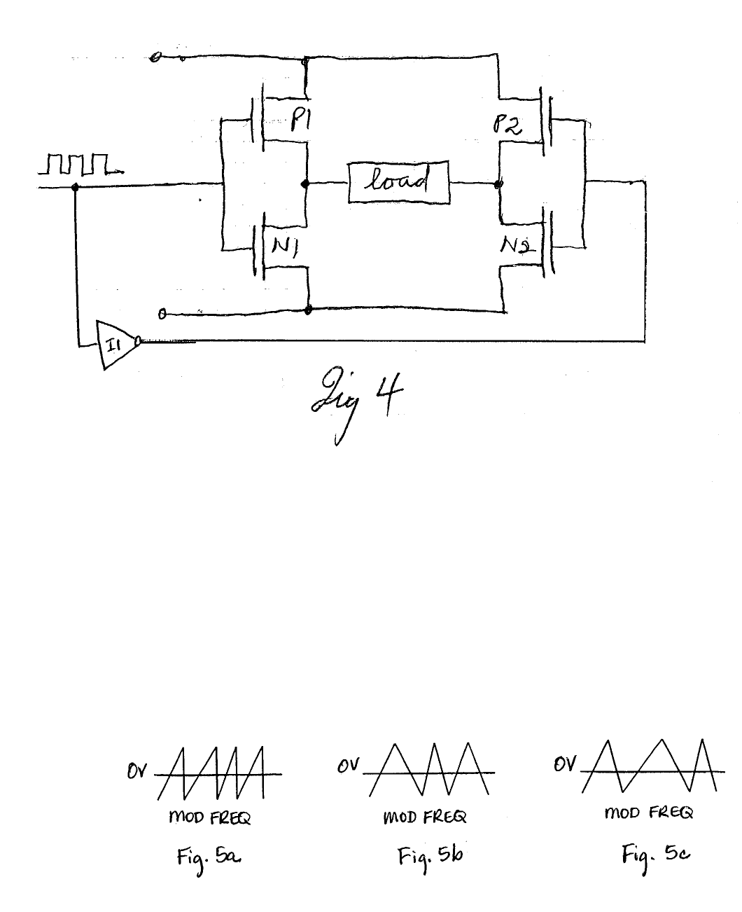

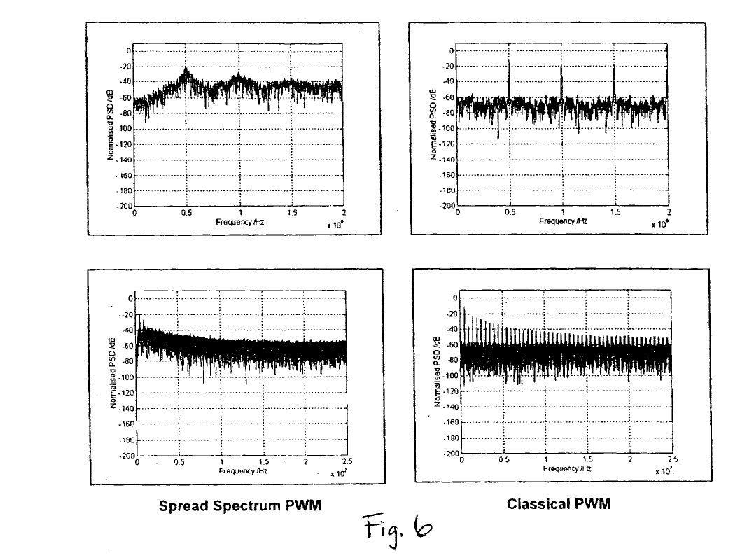

In the embodiment of the present invention of FIG. 3, the pulse width modulator is modified such that the square wave output from the modulator has edges that are varied in time in a random or pseudo-random fashion. In a preferred embodiment, this can be achieved by modifying the modulating sawtooth waveform so that its ramp rate varies cycle-to-cycle using a pseudo-random sequence to modify the time constant or ramp current (depending on the specific internal oscillator implementation). Alternatively, a triangular waveform may be used, with the rise and fall ramp rates of the waveform being varied appropriately. Exemplary waveforms may be seen on FIGS. 5a though 5c, illustrating a sawtooth waveform with varying ramp rate, a triangular waveform with varying periods, and a triangular waveform with varying ramp rates on each side of each triangle, respectively. The resulting square waveform output of the pulse width modulator has a spectrum that is substantially white at high frequencies, as shown in FIG. 6. Unfortunately, some of the random noise introduced at the modulator can appear in the audio signal band and degrade the signal-to-noise ratio of the circuit. However, when used in conjunction with a feedback loop as shown, the extra noise is treated in the same way as the H bridge non-idealities described previously. Specifically, this noise is high pass filtered away from the audio frequency range and good signal-to-noise ratio is achieved.

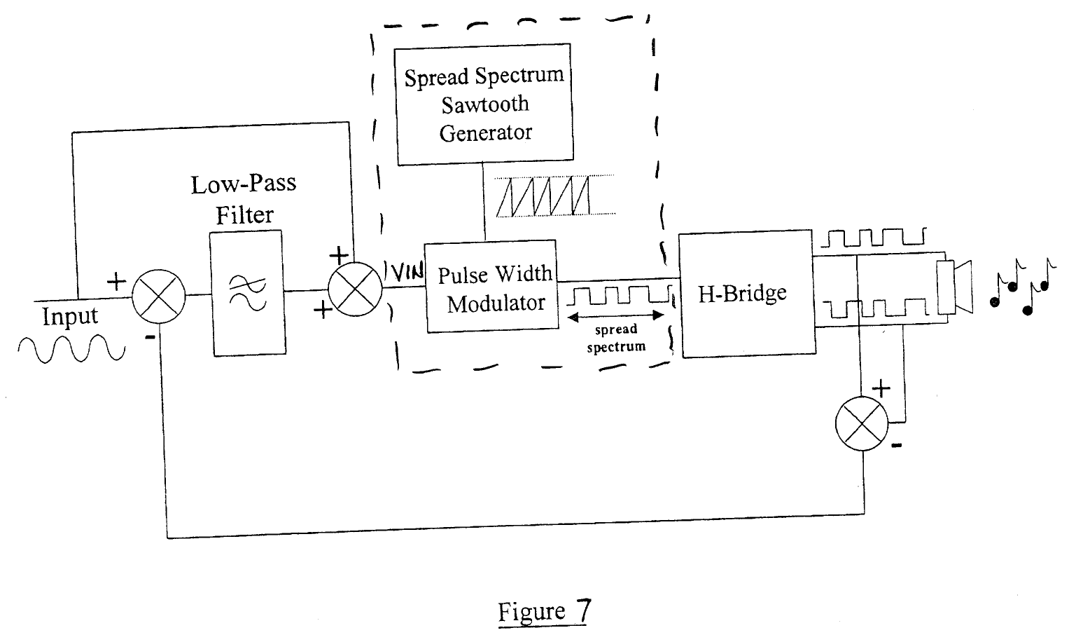

Using the embodiment of FIG. 3, no bulky external filter is required, and hence the square waveforms from the H bridge drive the speaker directly, and the square waveforms are also used as the feedback signals. This means that the input to the internal low pass filter, which in a preferred integrated circuit embodiment is an active filter, has significant high frequency content. As such, it can be advantageous to have a direct feed of the input signal through to the modulator such that the low pass filter needs only to deliver an error signal to the modulator rather than the input signal plus error signal as in FIG. 3. Such an embodiment is shown in FIG. 7, and can result in improved signal-to-noise and distortion performance of the system. In this system, the difference between the input signal and the feedback signal, which effectively is a combination of the input signal and an error signal, is provided to the low pass filter. Thus the input to the low pass filter is equal to, or substantially equal to, the error signal itself.

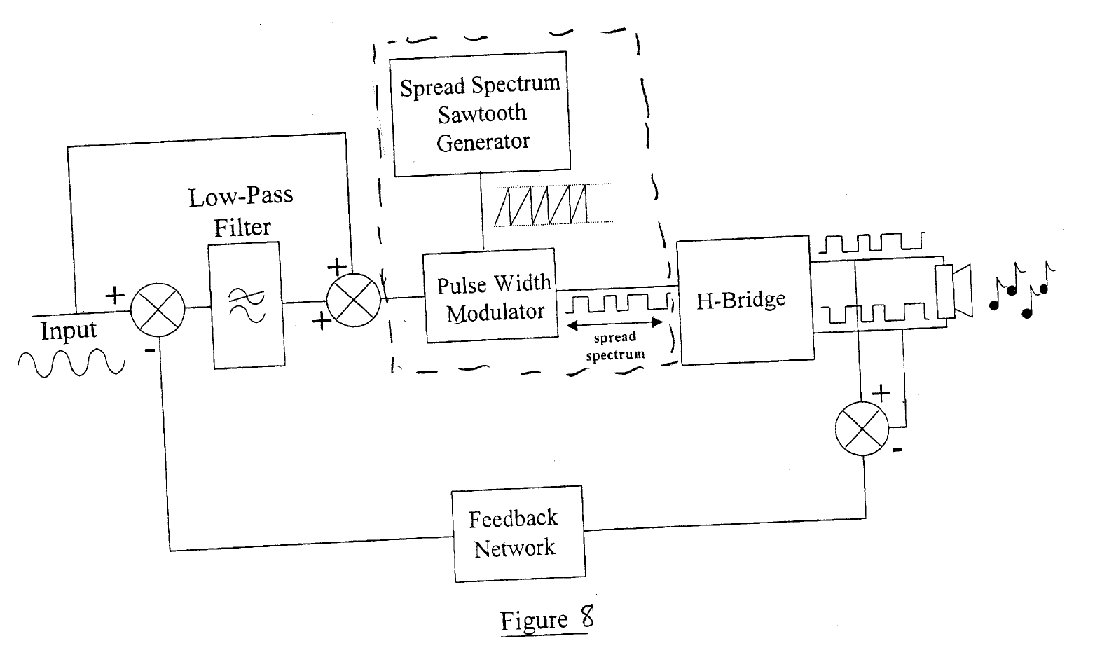

A further embodiment is shown in FIG. 8. Here, a feedback network is added between the H bridge outputs and the internal low pass filter. This network is used to shape the feedback waveform in such a way as to further improve the performance of the system. For example, this could be in the form of a low pass filter whose,cutoff frequency is high enough to not affect circuit stability, but low enough to provide some smoothing of the feedback signal in order to reduce the slew rate requirements for the active elements in the active low pass filters used in the preferred embodiments.

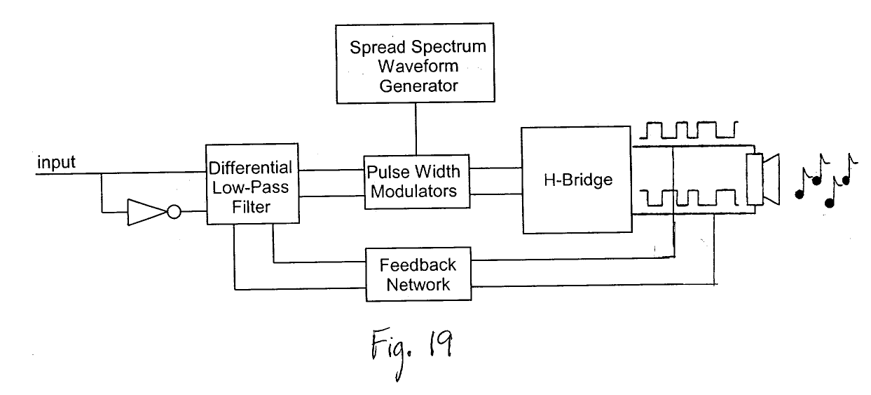

The embodiments of FIGS. 3, 7 and 8 illustrate symbolically the feedback of the differential output signal component and subsequent subtraction from the input signal. It should be noted that the specific implementation of the subtraction of one output from the other, and subsequent subtraction from the input signal, can be done in numerous ways. By way of example, the function of subtracting one output from the other can be achieved implicitly by feeding back both output signals to respective sides of a fully differential active low pass filter. In this way, the fully differential active filter sees both the common mode and differential components of the output waveforms but, by design, rejects the common mode component. In such an embodiment, the function of subtracting the output signal differential components from the input signal prior to low pass filtering can be achieved by applying the same input signal, and an inverted version thereof, as additional inputs to the fully differential active filter. In summary, the functions of differencing the output signals and subsequent subtraction from the input signal can be implicit to the function of the low pass filter, rather than separate functional blocks in the design. This is illustrated in FIG. 19. The functions are made explicit in FIGS. 3, 7 and 8 and in certain claims for descriptive clarity.

The modulator of FIGS. 3, 7 and 8 (shown within the dashed outlines in those Figures) may take various forms. By way of example, three alternate forms of pulse width modulator are described below. In that regard, the phrase pulse width modulator as used herein and in the claims that follow is used in the general sense to include possible manipulation of a modulator output to provide pulse width modulated waveforms of special characteristics.

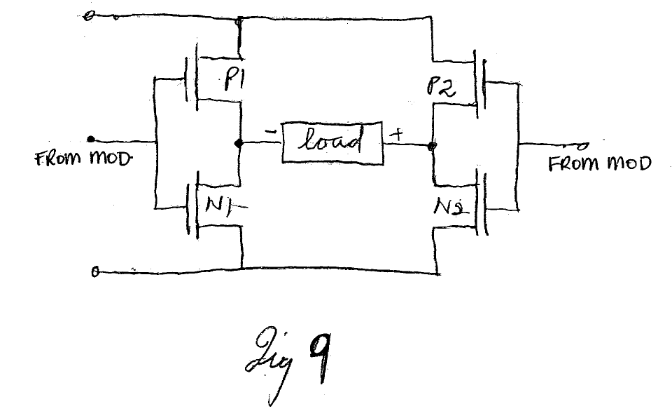

The first exemplary variation in the pulse width modulation is referred to as common mode idle. Here the inverter of an H bridge such as that of FIG. 4 is eliminated, and the two sides of the H bridge are separately driven by a respective line of a differential square wave signal from the modulator, as shown in FIG. 9. That differential square wave signal has both inverse components and common mode components responsive to the input signal. The inverse components have the same effect as described with respect to the pulse width modulator of FIG. 3, with the common mode components shorting the load by connecting both of the load terminals either to the circuit ground or the positive power supply.

The second exemplary variation in the pulse width modulator provides a ternary modulation. In effect, the common mode signals of the common mode idle are held in a single state, so the only switching of the H bridge is due to a differential signal, when it occurs. The third variation is to extend, in common mode, any modulator output pulse (a signal level pulse) that is too short to fully turn on the power switches of the H bridge. These and other exemplary variations, such as to not only to extend, in common mode, any modulator output pulse that is too short to fully turn on the power switches of the H bridge, but to further require at least a minimum switching activity every modulator cycle, are described more fully hereafter.

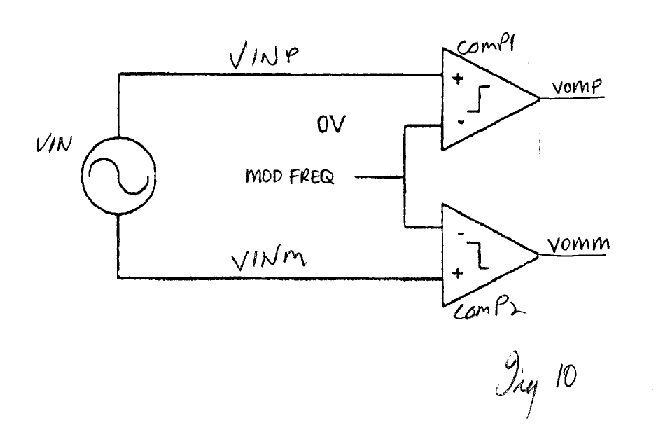

Now referring to FIG. 10, a differential input signal VIN (VINP and VINM) to be amplified is provided, where VINM=−VINP and VIN=VINP−VINM=2VINP. Such a signal in accordance with the present invention would correspond to the input to the pulse width modulator of FIGS. 3, 7 and 8 within the closed loop of the amplifier. The positive side input VINP is passed through a conventional pulse width modulator comprised of comparator COMP1 that compares the signal to a spread spectrum sawtooth or triangular waveform. The positive side input VINP causes an output of the modulator VOMP that is a square waveform with variable frequency and whose duty cycle is proportional to the instantaneous value of the input signal VINP. The negative side input signal VINM is passed through an identical pulse width modulator (comparator COMP2), generating a second square waveform VOMM.

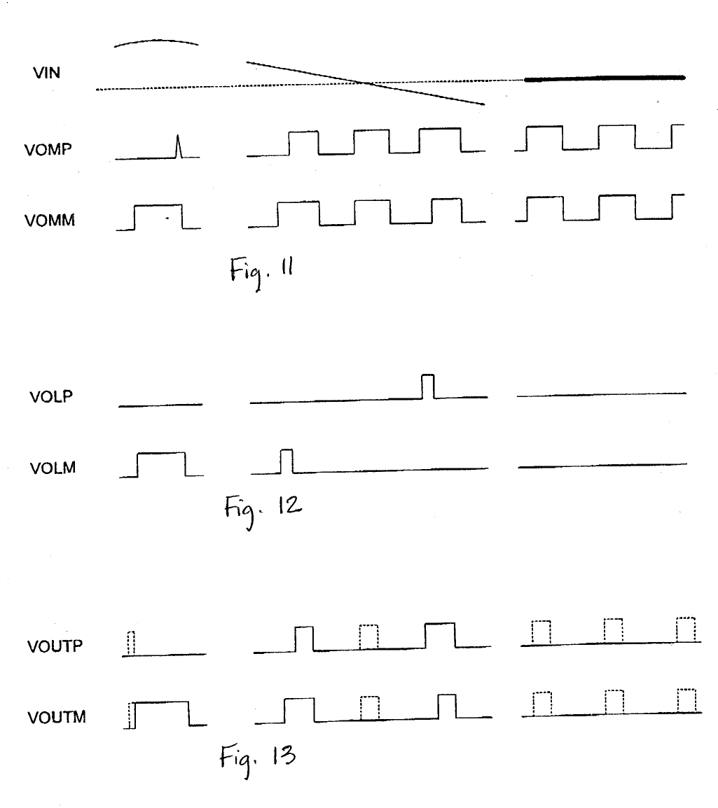

For a zero VIN signal (see FIG. 11), the waveforms VOMP and VOMM are in phase square waves with a 50% duty cycle. The common mode voltage is therefore also a square wave with a 50% duty cycle, while the differential voltage is zero. For positive and negative input signals VIN, the duty cycle of each waveform varies accordingly. Applying the signals VOMP and VOMM directly to an H bridge such as that of FIG. 9 provides the common mode idle variation previously described.

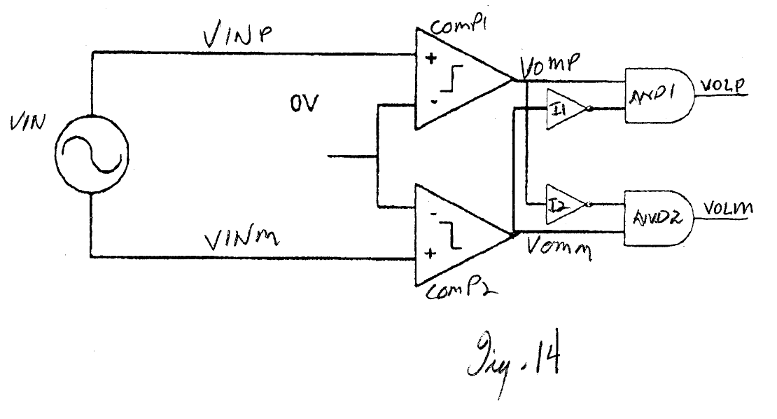

If instead of directly driving the H bridge, the two waveforms VOMP and VOMM pass through a simple logic circuit (inverters I1 and I2 and AND gates AND1 and AND2 shown on FIG. 14), the common mode voltage is held at zero without changing the differential voltage. The outputs signals VOLP and VOLM of the logic circuit are shown in FIG. 12. Note that both outputs cannot pulse at the same. Applying these signals directly to the H bridge of FIG. 9 provides the ternary operation previously described.

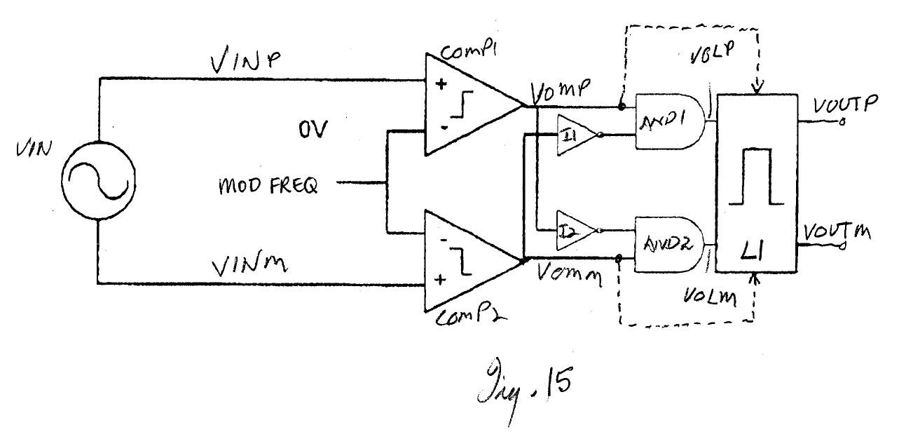

However, the outputs VOLP and VOLM of the pulse width modulator shown in FIG. 12 may pass through a further logic circuit L1 (see FIG. 15) to determine if a pulse is present on either VOLP or VOLM and whether it is above a certain well-defined width in time. If not, then a pulse is added equally to both sides (both VOLP and VOLM), such that, for small input signals, the differential mode voltage is still zero, but the common mode voltage contains pulses of at least a minimum duration. Exemplary outputs VOUTP and VOUTM are shown in FIG. 13 and may be used to drive an H bridge such as that of FIG. 9.

There are various ways of adding a pulse to both the VOUTP and VOUTM outputs simultaneously if a pulse of a width below the predetermined minimum width is detected on either of the signals VOLP or VOLM. By way of example, a pulse of a predetermined width could be added to both the VOUTP and VOUTM signals. In this case, the short pulse triggering the addition of the pulse of a predetermined minimum width would now have a width of the predetermined minimum width plus the shorter triggering pulse, while the other pulse would simply have the predetermined minimum width.

In one embodiment, the pulse width triggering the addition of a pulse to both of the VOUTP and VOUTM outputs can be represented as a pulse width in time of less than Δt. The leading edge of each VOLP and VOLM pulse is detected, and then the trailing edge is detected. When the trailing edge follows the leading edge by less than Δt, the pulse is extended and a pulse is initiated on the other side. Both pulses are then terminated at a time 2Δt after the leading edge of the triggering pulse was detected. Thus in this implementation, the triggering pulse is extended to a width of 2Δt, and a simultaneous pulse of a duration of not less than Δt or more than 2Δt is added to the other side during that extension.

In the preferred embodiment, the case where VOLP and VOLM are both exactly zero leads to VOUTP and VOUTM equal to zero. However, this case is only rarely of practical significance, because small offsets and delays in the real system tend to cause the outputs to maintain some switching activity from sample to sample, particularly where the modulation scheme is used within a feedback circuit with a filter, as in the present invention. Furthermore, in this embodiment, it should be noted that the additional pulse is only present for small input signals. For input signals above the well-defined threshold at which the logic circuit L1 determines that no additional pulse is required, switching activity on either VOUTP or VOUTM ceases. This has the benefit of reducing electromagnetic interference (EMI) emissions and maintaining maximum possible input signal range.

In another embodiment, the additional pulse is triggered by one of the comparator outputs VOMP or VOMM (which, in this embodiment, are fed directly to L1, as indicated by the dashed arrows in FIG. 15). Referring to FIG. 13, consider first the case where the rising edge of VOMM occurs before the rising edge of VOMP. In this case, the rising edge of VOMM triggers the respective output VOUTM to go high. The subsequent rising edge of VOMP then triggers the rising edge of the additional pulse on the respective VOUTP. When the additional pulse is terminated after a well-defined delay of width Δt, both VOUTP and VOUTM fall simultaneously. With a similar argument, in the case where the rising edge of VOMP occurs before the rising edge of VOMM, now VOMM triggers the rising edge of the additional pulse on the respective VOUTM.

In the case where the rising edges of VOMP and VOMM occur exactly simultaneously, as is the ideal case for zero input signal, an additional pulse of width Δt appears identically on both VOUTP and VOUTM as indicated in FIG. 13 (dashed pulses). In the case where the falling edge of the additional pulse would occur after the common falling edge of both VOMP and VOMM, the common falling edge of VOMP and VOMM overrides the additional pulse, such that the additional pulse is cut short by the common falling edge. For large signal amplitudes, this has the effect of reducing the width of the additional pulse linearly as the input signal increases toward full scale (defined as the point at which the duty cycle on either output reaches 100%). The point at which the additional pulse begins to decrease in width is approximately determined by the duty cycle of the additional pulse. For example, if the additional pulse has a duty cycle of 10%, then the additional pulse will begin reducing in width when the input signal reaches approximately 10% below full scale. This is a very acceptable compromise to removing the additional pulse completely, since typically class D amplifiers distort due to other considerations at close to full scale input signal, hence the narrower additional pulses at this point become of little or no practical significance.

This embodiment differs from the preferred embodiment in two respects. Firstly, the case where VOLP and VOLM are both exactly zero now results in an additional pulse on both outputs rather than zero on both outputs. This situation can be preferable compared with the previous embodiment, whose outputs will both be zero at sampling instances where VOLP and VOLM are exactly zero or have incomplete pulses below a threshold required to activate the sensing circuit in L1. By way of example, with the class D amplifier incorporating a feedback circuit whose feedback path has a finite common mode rejection, the intermittent zeros on both outputs can lead to smearing of the common mode signal in the frequency domain that could appear as noise in the differential signal path. This second embodiment prevents this behavior. The second difference is that, at all input signals up to full scale, both outputs maintain switching activity (at a minimum switching pulse width each pulse width modulator cycle). Again, this situation may be preferred over the previous embodiment, where a transition in the common mode behavior occurs when the input signal reaches the amplitude where the additional pulse no longer appears on one of the outputs. This transitional behavior, although ideally rejected by the differential system, may cause noise and distortion to occur due to the finite common mode rejection of the circuit.

These implementations are exemplary only however, as other implementations may be used as desired.

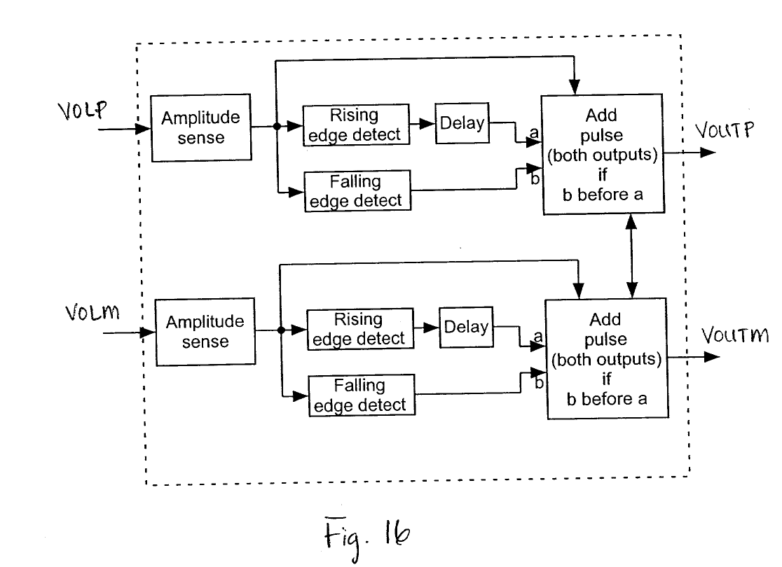

A block diagram for an exemplary logic circuit L1 may be seen in FIG. 16. This diagram illustrates the general logic of the logic circuit, as opposed to a detailed circuit diagram for the circuit, as the details of any circuit implementation may vary and are not important to the present invention. As may be seen in the Figure, the outputs VOLP and VOLM of AND gates AND1 and AND2, respectively, are each applied to a respective amplitude sense circuit which simply ignores pulses below a predetermined height, or below a predetermined fraction of the height of a full height pulse. In that regard, it should be recognized that the circuitry hereinbefore described which results in the signals VOLP and VOLM is signal processing circuitry, not power switching circuitry, so as to be capable of very high speed operation in comparison to the power switching circuitry of an H bridge, such as the exemplary H bridge of FIG. 9. Consequently, a pulse in the VOLP signal or the VOLM signal which is not a full height pulse is caused by the pulse width being so short in time duration that the trailing edge of the pulse intersects the leading edge of the pulse before full pulse height is reached. This, then, represents such a short pulse as to not be significant in the operation of the amplifier, and accordingly is ignored by the amplitude sense.

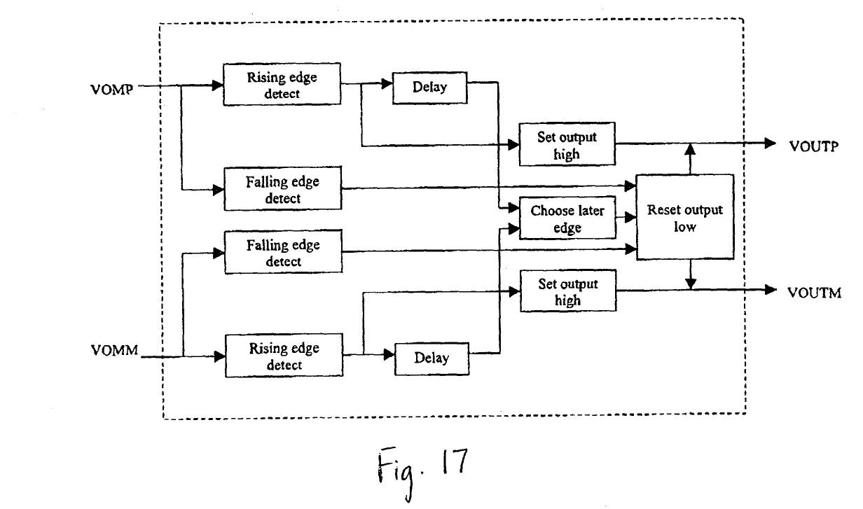

A pulse of adequate height is passed to the respective rising edge detect circuit and a falling edge detect circuit, the outputs of which, after delay of the rising edge detect circuit output, are provided as the respective signals a and b. The delay imposed on the rising edge of the pulse is in accordance with the minimum pulse width to be allowed. If the pulse VOLP or VOLM (both will not occur at the same time) is of adequate width, the pulse is then passed to the respective output VOUTP or VOUTM. If, on the other hand, the pulse is below the minimum pulse width, then an appropriate simultaneous pulse is added to both output pulses VOUTP and VOUTM, the added pulse as an extension of one of the output pulses VOUTP or VOUTM and as an original pulse to the other. The width of the pulse added may be the same as or different from the minimum pulse width below which the pulse will be added, or may be of the width needed to extend the short pulse to some predetermined pulse width above the minimum pulse width triggering the addition of the pulse, such as twice or more the minimum pulse width. A block diagram for a second exemplary logic circuit L1 may be seen in FIG. 17. In this case, the comparator outputs VOMP and VOMM are applied to the respective rising edge detector circuits, whose outputs are used to set VOUTP and VOUTM high respectively. Each rising edge detector output is then delayed, and then both of the delayed rising edges are taken and the latter of the two is selected. This latter edge is then used to reset both outputs VOUTP and VOUTM. Additional edge detectors are used to detect the common falling edge of the VOMP and VOMM, and the output of these edge detectors are also used to reset the outputs VOUTP and VOUTM. In this way, the reset edge of the outputs VOUTP and VOUTM is overridden by the reset edge of the comparator outputs VOMP and VOMM. This must be done to maintain overall synchronization of the system with the sawtooth oscillator.

As shall subsequently be seen, because all additional pulses are added in the common mode, they do not affect the differential signal provided to the H-bridge. They do, however, assure that the much slower switching transistors in the H-bridge are never partially turned on and then turned off, giving rise to the non-linearity described in one of the prior art patents herein before referred to. Instead, the adding of the pulse to both the VOLP and VOLM signals, when necessary, assures linearity in the differential signal applied to the H-bridge, and accordingly linearity in the output thereof.

The pulse, when added to both the VOUTP and VOUTM pulses, could be added at the beginning of a short pulse, though it is believed that it is a simpler implementation to add the pulse when a short pulse is ending.

The final outputs VOUTP and VOUTM of the logic circuit L1 are used to drive an H bridge coupled to a load on the amplifier output, as shown in FIG. 9. Although the H-bridge illustrated in FIG. 9 is comprised of two n-channel switching transistors N1 and N2 and two p-channel transistors P1 and P2, it should be noted that the present invention is not limited to use with this specific H-bridge implementation. By way of example, a popular alternative H-bridge implementation would incorporate two n-channel transistors in place of the two p-channel transistors and whose control terminals are driven by some means to a voltage sufficiently above the power supply voltage to turn on the devices, and then to a ground or negative power supply voltage to turn them off, this control voltage being provided in the correct sense to ensure that the H-bridge output switching behavior is the same as that of FIG. 9. The specific exemplary implementation shown in FIG. 9 is described here for clarity. When both inputs VOUTP and VOUTM to the H-bridge shown in FIG. 9 are low, p-channel transistors P1 and P2 will both be on, shorting the load by the common connection of the sources of the two p-channel transistors. When both inputs VOUTP and VOUTM to the H-bridge are high, the two p-channel transistors P1 and P2 will be turned off and the two n-channel transistors N1 and N2 will be turned on, shorting the load through the common connection of the sources of the n-channel transistors. Thus the common mode output to the H-bridge results in the shorting of the load, regardless of whether the two inputs to the H-bridge are both high or both low. Consequently, the addition of any minimum pulse to both signals VOUTP and VOUTM does not change the effective connection of the load, that is a shorted connection, though does change which two transistors are turned on to cause that short.

In the case of a differential signal wherein VOUTP is high during some period when VOUTM is low, n-channel transistor N1 and p-channel transistor P2 will be turned on, with the other two transistors turned off. This connects the positive side of the load to the positive power supply and the negative side of the load to the negative power supply. Similarly, if the signal VOUTP is low and the signal VOUTM is high, p-channel transistor P1 and n-channel transistor N2 will be turned on, with the other two transistors turned off, thereby connecting the negative side of the load to the positive power supply terminal and the positive side of the load to the negative power supply terminal. The net effect is a ternary state operation of the H-bridge, namely connection of the load to the power supply with the positive sense on the occurrence of a positive differential input, connection of the load to the power supply in a negative sense on the occurrence of a negative differential input, and shorting the load during periods of zero differential input, regardless of the instantaneous common mode voltage.

Thus, in operation of this embodiment, partial pulses in the signal processing circuitry are ignored. Also, pulses in the VOLP and VOLM signals (FIGS. 13, 15, 16 and 17) which are of sufficient duration to assure full turn-on of the appropriate pair of switching transistors driving the load before turn-off is initiated (preferably with at least some minimum on time) will be passed directly to the H-bridge without modification. However, full height pulses in the VOLP and VOLM signals which are too short in duration for the full switching of the transistors in the H-bridge will result in the adding of the pulse on both signals VOUTP and VOUTM to drive the H-bridge to assure full switching.

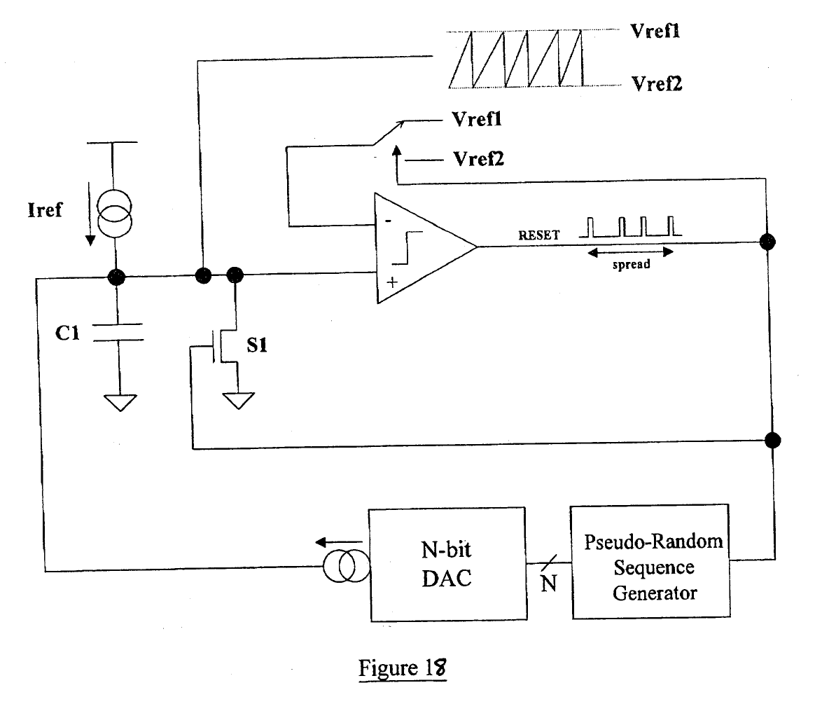

There are many possible methods of generating a sawtooth or triangular waveform with a variable frequency for use in the present invention. A preferred embodiment is shown in FIG. 18. In this embodiment, a current source is used to charge a capacitor. When the voltage on the capacitor reaches a first fixed threshold voltage, the capacitor voltage is rapidly discharged with a switch. When the capacitor voltage reaches a second fixed threshold voltage that is lower than the first, the switch is turned off and the capacitor begins charging again. Hence, the voltage waveform on the capacitor has a sawtooth shape and ramps between the two threshold voltage values. In this implementation, the control voltage for the switch is a digital pulse of short duration. This control pulse is used as a clock pulse to update the outputs of a digital pseudo-random sequence generator, whose digital outputs are then converted to a current using a simple current-switching digital-to-analog converter circuit, and whose current output is used to add or subtract current from the current source that is used to charge the capacitor. In this way, a sawtooth is generated whose ramp rate changes on a sample-by-sample basis, but whose ramp remains substantially linear from sample to sample.

This modulation scheme overcomes the linearity limitations caused by switching pulses that are too short to fully turn on the power devices before initiating turnoff of the devices, while also providing reduced ripple at small output signals. By virtue of the variable frequency of the input waveform, the placement in time of the edges of the minimum pulse is such that the high frequency spectrum of the output voltage is substantially flat (white) compared with the prior art modulation schemes, and hence electromagnetic interference emissions from the circuit can be kept substantially below regulatory requirements without the need for using an external filter between the output pins of the chip and the load.

The frequency range of the random or pseudo random variation in the pulse width modulators effects the spreading of the noise. Consequently, the wider that frequency range, the lower the peak amplitudes of noise at frequencies of concern for EMI limitations. However, a wider frequency range increases the components of noise that fall into the audio frequency range. Accordingly, there is a tradeoff that must be made. In one embodiment, a modulator center frequency of 1 MHz is used, with a pseudo random frequency variation of ±10%.

Thus the present invention applies spread spectrum techniques to closed loop class D amplifiers in such a way that the high frequency spectrum of the PWM signal is substantially flat, while at the same time the audio content of the waveform at low frequency maintains a high signal-to-noise ratio. The invention helps enable the use of high performance class D amplifiers without the need for costly output filters.

While certain preferred embodiments of the present invention have been disclosed herein, such disclosure is only for purposes of understanding the exemplary embodiments and not by way of limitation of the invention. It will be obvious to those skilled in the art that various changes in form and detail may be made in the invention without departing from the spirit and scope of the invention as set out in the full scope of the following claims. Using this invention, Electromagnetic Interference (EMI) emissions from the circuit can be kept substantially below regulatory requirements without the need for expensive external filtering and/or shielding external to the integrated circuit.

What is claimed is:

1. A method of class D amplification of an input signal comprising:
pulse width modulating a first signal using a pulse width modulator frequency that is varied dynamically in time;
driving an H bridge responsive to an output of the pulse width modulator, an output of the H bridge being coupled to a load;
feeding back the output of the H bridge to provide an error signal responsive to the difference between the input signal and the feedback signal, the first signal being responsive to the error signal.

2. The method of claim 1 wherein the frequency of the pulse width modulator is varied in a pseudo random manner.

3. The method of claim 2 wherein the frequency is varied by approximately ±10%.

4. The method of claim 3 wherein the frequency is approximately 1 MHz.

5. The method of claim 2 wherein the first signal is responsive to the error signal after the error signal is low pass filtered.

6. The method of claim 5 wherein the low pass filtering is done by an active low pass filter.

7. The method of claim 5 wherein the first signal is also responsive to the input signal.

8. The method of claim 7 wherein the error signal is responsive to the difference between the input signal and the feedback signal after the feedback signal is passed through a feedback network.

9. The method of claim 5 wherein the error signal is responsive to the difference between the input signal and the feedback signal after the feedback signal is passed through a feedback network.

10. The method of claim 2 wherein the pulse width modulator outputs a square wave of varying duty cycle, and the H bridge couples the load to the power supply with a polarity dependent on the present state of the square wave.

11. The method of claim 2 further comprising converting the pulse width modulator outputs to a ternary signal, and driving the H bridge with the ternary signal.

12. The method of claim 11 further comprising adding a pulse in common mode to both sides of the ternary signal when a pulse is detected that is below a first predetermined pulse width.

13. The method of claim 12 wherein the first predetermined pulse width is a pulse width at least adequate to fully turn on the switches of the H bridge.

14. The method of claim 13 wherein the pulses added in common mode have a pulse width at least adequate to increase the pulse width on both sides of the ternary signal to the first predetermined pulse width.

15. The method of claim 12 wherein the added pulses have a second predetermined width.

16. The method of claim 15 wherein the second predetermined width is approximately twice the first predetermined width.

17. The method of claim 12 wherein the width of pulses added in common mode is reduced as the differential input signal approaches a full-scale value.

18. The method of claim 12 wherein switching activity is maintained on both sides of the ternary signal on each cycle of the pulse width modulator.

19. The method of claim 12 wherein the pulse width modulating comprises use of a sawtooth waveform having a varying ramp rate.

20. The method of claim 12 wherein the pulse width modulating comprises use of a triangular waveform having a varying triangular waveform period.

21. The method of claim 12 wherein the pulse width modulating comprises use of a triangular waveform, the sides of the triangular waveform having varying ramp rates.

22. A method of class D amplification of an input signal comprising:
coupling an input signal to an active differential low pass filter;
pulse width modulating a differential output signal of the active differential low pass filter using a pulse width modulator frequency that is varied dynamically in time;
driving an H bridge responsive to a differential output of the pulse width modulator, a differential output of the H bridge being coupled to a load;
feeding back the differential output of the H bridge to the active differential low pass filter.

23. The method of claim 22 wherein the frequency of the pulse width modulator is varied in a pseudo random manner.

24. The method of claim 23 wherein the frequency is varied by approximately ±10%.

25. The method of claim 24 wherein the frequency is approximately 1 MHz.

26. The method of claim 22 wherein the differential output of the H bridge is fed back through a feedback network to the active differential low pass filter.

27. The method of claim 22 wherein the pulse width modulator outputs a square wave of varying duty cycle, and the H bridge couples the load to the power supply with a polarity dependent on the present state of the square wave.

28. The method of claim 22 further comprising converting the pulse width modulator outputs to a ternary signal, and driving the H bridge with the ternary signal.

29. The method of claim 28 further comprising adding a pulse in common mode to both sides of the ternary signal when a pulse is detected that is below a first predetermined pulse width.

30. The method of claim 29 wherein the first predetermined pulse width is a pulse width at least adequate to fully turn on the switches of the H bridge.

31. The method of claim 30 wherein the pulses added in common mode have a pulse width at least adequate to increase the pulse width on both sides of the ternary signal to the first predetermined pulse width.

32. The method of claim 29 wherein the added pulses have a second predetermined width.

33. The method of claim 32 wherein the second predetermined width is approximately twice the first predetermined width.

34. The method of claim 29 wherein the width of pulses added in common mode is reduced as the differential input signal approaches a full-scale value.

35. The method of claim 29 wherein switching activity is maintained on both sides of the ternary signal on each cycle of the pulse width modulator.

36. The method of claim 29 wherein the pulse width modulating comprises use of a sawtooth waveform having a varying ramp rate.

37. The method of claim 29 wherein the pulse width modulating comprises use of a triangular waveform having a varying triangular waveform period.

38. The method of claim 29 wherein the pulse width modulating comprises use of a triangular waveform, the sides of the triangular waveform having varying ramp rates.
